(19) United States
(12) Patent Application Publication
(10) Pub. No.: US 2006/0207496 A1
(43) Pub. Date: Sep. 21, 2006

(54) Method of manufacturing domain inverted crystal

(76) Inventors: Masahiro Koto, Itami-shi (JP); Hirokazu Taniguchi, Itami-shi (JP); Shigeo Maeda, Kawanishi-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/548,653

(22) PCT Filed: Mar. 12, 2004
(86) PCT No.: PCT/JP04/03309

§ 371 Date: Sep. 13, 2005

(30) Foreign Application Priority Data
Mar. 14, 2003 (JP) 2003070802

(51) Int. Cl. C30B 1/00; C30B 5/00; C30B 28/02; C30B 3/00

(52) U.S. Cl. 117/4

(57) ABSTRACT

A first electrode is partially contacted with a domain to be polarization-inverted 2 on one plate face of a nonlinear optical crystal substrate 1, a second electrode is contacted with the other plate face of the substrate, and a polarization inversion voltage is applied between the both electrodes. At this time, the electrode is so formed that the contact area of the first electrode 3 with the plate face satisfies particular conditions, and the domain to be polarization-inverted is entirely or partially polarization-inverted by the application of a polarization inversion voltage. The aforementioned particular conditions are that each contact area 3 is dot-like so that plural contact areas 3 can be present independently within individual domains to be polarization-inverted 2, and individual dot-like contact areas have an area of 0.00785 μm ²-7850 μm² and a shape included in a circle having a diameter of 100 μm. As a result, a polarization inverted crystal having high quality can be obtained more easily.

### TECHNICAL FIELD

The present invention relates to a production method of a polarization inverted crystal (namely, a nonlinear optical crystal wherein a periodic polarization inverted structure (periodically domain-inverted structure) is formed).

### BACKGROUND ART

It is known that a ferro-electric crystal (particularly a nonlinear optical crystal) can be utilized as a wavelength converting element by periodically inverting the direction of spontaneous polarization for every specific domain (e.g., JP-A-6-110095).

A structure wherein the direction of spontaneous polarization is inverted for every specific domain as mentioned above is a periodic polarization inverted structure (hereinafter a polarization inverted structure), and a nonlinear optical crystal partly or entirely imparted with the polarization inverted structure is a polarization inverted crystal.

A polarization inverted crystal can be used as an element for various wavelength conversions, such as Second Harmonic Generation (SHG), Optical Parametric Oscillation (OPO), Difference Frequency Generation (DFG), Sum Frequency Generation (SFG) and the like, by changing the period of its polarization inverted structure. Therefore, application of a wavelength converting element using a polarization inverted crystal to the fields of optical communication, optical information processing, gas detection and the like has been studied, since it can realize a wide range of wavelength conversion from blue visible bounds to infrared bounds.

FIGS. 15(a) and 15(b) each show an example of a polarization inverted crystal, wherein an inverted domain R1 with inverted polarization direction and a non-inverted domain N1 with the original crystal polarization direction are alternately arranged at a predetermined period in a crystal substrate 11 to form a stripe pattern. In FIG. 15(a), a polarization inverted structure is formed on the surface layer of a nonlinear optical crystal substrate (hereinafter “crystal substrate”) 11 and a waveguide 12 is formed to cross the structure. In FIG. 15(b), a polarization inverted structure is formed in the entirety of a crystal substrate to give what is called a bulk type wherein the optical path is not limited. When an input light L10 to be wavelength-converted alternately passes a non-inverted domain and an inverted domain, an output light L20 is produced and emitted, which output light L20 is wavelength-converted by a nonlinear optical effect of crystal and a quasi-phase matching of a polarization inverted structure.

As a preferable production method of conventional polarization inverted crystals, the methods described in U.S. Pat. No. 5,800,767 (FIG. 16) and U.S. Pat. No. 5,193,023 can be mentioned. According to this method, a resist pattern 22 made of an insulator is so formed on one plate face (upper surface of the substrate in this Figure; +z-plane) of a crystal substrate (z plate) 11 that only the domain to be polarization inverted is exposed, and an electrode layer 23 made of a metal electrode material is uniformly formed thereon, as shown in FIG. 16. As a result, the electrode layer 23 contacts only with the domain to be polarization inverted (hereinafter an electrode of the contacted part is to be referred to as an “upper electrode”) and acts as an electrode for inversion. In the example shown in this Figure, a liquid electrode 24 is further contacted on the electrode layer 23, which in turn enables application of a uniform voltage to the entire surface of the electrode layer 23.

A liquid electrode (liquid electrolyte) 31 contacts the entire surface of the other plate face (lower surface of the substrate in this Figure; −z-plane) in FIG. 16. A container and the like for contacting with a liquid electrode is not shown. Both electrodes are each connected with an electric power-supply unit S10 (not shown) for applying an inversion voltage, and when a polarization inversion voltage is applied between both electrodes (+electric potential is applied to +Z-plane and -electric potential is applied to −Z-plane), the spontaneous polarization direction of crystal is inverted to give a polarization inverted crystal. In FIG. 16, an electric field generated by polarization inversion voltage is shown with an arrow.

In the above-mentioned polarization inversion method, when only the area beneath an upper electrode 23 (hatched part 11a in the opposite direction) is polarization-inverted, whose ideal state is shown in FIG. 17(a), the quality of the polarization inverted structure depends solely on the precision of formation of the electrode pattern and no particular problem is produced.

However, in an actual polarization inversion processing, as shown in FIG. 17(b), a polarization-inverted domain is formed not only in a domain beneath an upper electrode 23 but extends from the upper electrode 23, like a domain 11b in this Figure. It is difficult to positively suppress such overflow from the polarization-inverted domain, and a countermeasure such as setting the width of an upper electrode narrower in anticipation of the amount of overflow and the like has been taken. In other words, the size of a polarization-inverted domain depends on the results of the inversion step and production of a polarization inverted structure having a high precision period has been difficult. To inhibit overflow from the polarization-inverted domain, strict control of the applied voltage is required, and repeated production of polarization inverted crystals having similar quality has not been easy.

Taking note of the contact area between a crystal substrate face and an upper electrode, a phenomenon wherein polarization inversion proceeds from the corner of the circumference of a contact area due to an edge-effect by which electric fields gather to the edge having a shape of an outer circumference of the upper electrode is seen, which becomes a problem.

To be specific, as shown in FIG. 18, the arrangement pattern of the upper electrode to form a polarization inverted structure is a stripe-like pattern, wherein individual electrode shape (=shape of contact area) 12 becomes a band as shown with a dashed line. When a polarization inversion voltage is applied to such a band electrode, the edge-effect causes polarization inversion first in the both ends of the band, and when application of the voltage is continued, the inversion proceeds from the both ends toward the center, and finally, the entire area of the band is inverted.

However, the inversion actually proceeds not only from the both ends toward the center but also toward the period direction (direction toward the neighboring electrode). Thus, when the whole inversion is completed, the both ends inverted first have spread too much in the period direction (hatched part 13 in this Figure).

Consequently, problems including a nonuniformly inverted structure (particularly, inversion ratio) in the crystal substrate surface, and joining of the neighboring inverted domains to cause failure in functioning as a polarization inverted structure occur. In addition, since the voltage applying conditions vary depending on the polarization inversion period and the size of electrode area, specific conditions need to be determined for each shape of the product.

### DISCLOSURE OF THE INVENTION

The problem of the present invention is to provide a production method of a polarization inverted crystal that can solve the above-mentioned problems and can easily afford a polarization inverted crystal having high quality.

The present invention is characterized by the following.

(1) A production method of a polarization inverted crystal, which comprises a step of bringing a first electrode into partial contact with domain(s) to be polarization-inverted, which domains are present in the number of not less than 1 in one plate face of a nonlinear optical crystal substrate, bringing a second electrode into contact with the other plate face of the substrate, and applying a polarization inversion voltage between the both electrodes,

wherein, in the aforementioned step, the electrodes are so formed that the contact area of the first electrode relative to the plate face satisfies the conditions of the following (A), and the domain to be polarization-inverted is entirely or partially polarization-inverted by the application of a polarization inversion voltage:

(A) respective contact areas are dispersed like dots in individual domains to be polarization-inverted such that plural contact areas are independently present, and individual dot-like contact areas have an area of 0.00785 μm²-7850 μm² and a shape included in a circle with a diameter of 100 μm.

(2) The production method of the above-mentioned (1), wherein the domain to be polarization-inverted is entirely polarization-inverted by the application of a polarization inversion voltage.

(3) The production method of the above-mentioned (1), wherein the domain to be polarization-inverted is partially polarization-inverted by the application of a polarization inversion voltage and the partial polarization inversion is any of the modes of the following (i)-(iv):

(i) a mode wherein an area about the same as the contact area of the first electrode is polarization-inverted,

(ii) a mode wherein the polarization inverted domain spreads from the contact area of the first electrode to a surrounding area, and the polarization inverted domains are not joined with each other but independently present,

(iii) a mode wherein the polarization inverted domain spreads from the contact area of the first electrode to a surrounding area, and partial areas of the polarization inverted domain are joined with each other, and

(iv) a mode wherein the inverted domain spreads from the contact area of the first electrode to a surrounding area, the inverted domains are joined with each other but an area free of polarization-inversion remains.

(4) The production method of the above-mentioned (1), wherein an insulation film is formed on one plate face of the nonlinear optical crystal substrate, an opening having a shape of the above-mentioned contact area is formed in the insulation film to expose the plate face within the opening, and an electrode is contacted with the exposed plate, which is used as the first electrode.

(5) The production method of the above-mentioned (1), wherein two kinds of stripe insulation films different from each other in at least the longitudinal direction of these bands are layered intersectionally on one plate face of the nonlinear optical crystal substrate, an exposed area surrounded by belts of these two kinds of stripe insulation films is used as the above-mentioned contact area, and an electrode is contacted with said area to give the first electrode.

(6) The production method of the above-mentioned (1), wherein the above-mentioned contact area has a shape of a circle, an ellipse or a polygon with round corners.

(7) The production method of the above-mentioned (1), wherein a gap between the adjacent areas from the plural contact areas present in the domain to be polarization-inverted is not more than 5 μm under the above-mentioned conditions (A).

(8) The production method of the above-mentioned (1), wherein the nonlinear optical crystal substrate is a crystal substrate which is so cut that the substrate contains the Y crystal axis in its main face, and the plural contact areas present in the domain to be polarization-inverted are arranged to lie in continuance in the Y axis direction under the above-mentioned conditions (A).

(9) The production method of the above-mentioned (1), wherein the nonlinear optical crystal substrate is a crystal substrate made of LiNbO₃, LiTaO₃, or LiNbO₃ or LiTaO₃ doped with other element.

### BRIEF DESCRIPTION OF THE DRAWINGS

FIG. 1 is a schematic diagram to explain the production method of the present invention and shows an embodiment wherein the whole domains to be polarization-inverted are polarization-inverted and hatching is applied to distinguish domains.

FIG. 2 is a partially enlarged view showing one example of an embodiment wherein the domains to be polarization-inverted are partially polarization-inverted in the production method of the present invention.

FIG. 3 is a partially enlarged view showing another example of an embodiment wherein the domains to be polarization-inverted are partially polarization-inverted in the production method of the present invention.

FIG. 4 is a partially enlarged view showing another example of an embodiment wherein the domains to be polarization-inverted are partially polarization-inverted in the production method of the present invention.

FIG. 5 is a schematic diagram explaining the definition of the contact area in the present invention.

FIG. 6 is a schematic diagram exemplarily showing the shape of the contact areas and the arrangement patterns in the present invention.

FIG. 7 is a schematic diagram exemplarily showing the shape of the contact areas and the arrangement patterns in the present invention.

FIG. 8 is a sectional view showing the structure of an electrode satisfying the conditions of the contact area in the production method of the present invention.

FIG. 9 is a perspective view showing a preferable embodiment wherein openings are formed using an insulation film in the production method of the present invention.

FIG. 10 is a graph showing the relationship between the size of a dot-like contact area and the standard deviation of inversion ratios in Examples of the present invention.

FIG. 11 is a graph showing the dispersion in inversion ratios of FIG. 10 based on conversion efficiency.

In FIG. 12, FIG. 12(a) is a microscopic photograph showing an arrangement pattern of openings in the contact area formed in an insulation film in Example 2 of the present invention, and FIG. 12(b) is a microscopic photograph showing a polarization inverted structure obtained by the contact area in FIG. 12(a).

FIG. 13 is a microscopic photograph showing an end of the individual polarization inverted domains in the polarization inverted structure shown in FIG. 12(b).

FIG. 14 is a microscopic photograph showing an arrangement pattern of openings in the contact area formed in an insulation film in Example 3 of the present invention.

FIG. 15 is a perspective view schematically exemplifying the appearance of a polarization inverted crystal.

FIG. 16 is a sectional view showing an example of an electrode structure formed to apply a polarization inverted electrode in a production method of a conventional polarization inverted crystal.

FIG. 17 is a sectional view showing spread of the inside of the crystal of a polarization inverted domain formed by a conventional production method.

FIG. 18 shows spread of the polarization inverted domain on the substrate surface when polarization-inversion was performed by a conventional production method.

The symbols in the above-mentioned Figures each show the following constituent elements. 1: nonlinear optical crystal substrate, 2: domain to be polarization-inverted (predetermined domain), 3: contact area, 4: polarization inverted domain.

### BEST MODE FOR EMBODYING THE INVENTION

In the following, a polarization inverted domain intended to be finally obtained in design or polarization inverted domain to be wholly inverted in design (i.e., domain to be polarization-inverted) is referred to as a “predetermined domain”, the first electrode to be disposed within the predetermined domain is referred to as an “upper electrode” or “the first electrode”, and a second electrode to be disposed on the other face of the crystal substrate is referred to as a “lower electrode” or “the second electrode”, in the explanation of the present invention.

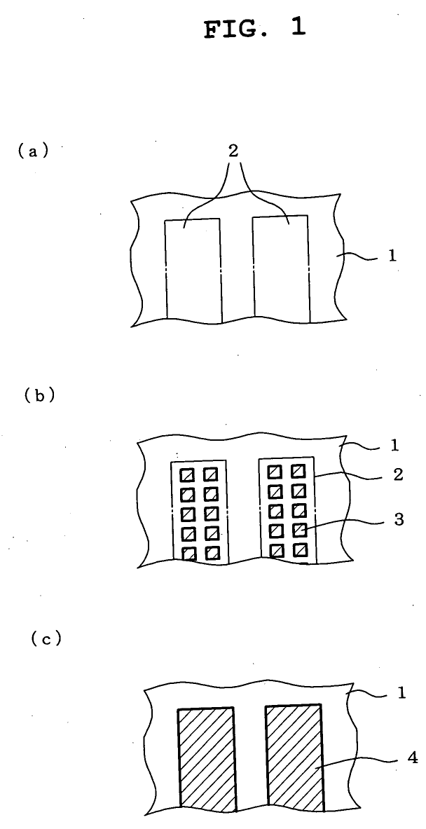

FIG. 1 (a) shows a part of the plate face of a crystal substrate 1 before forming a polarization inverted structure, wherein predetermined domains 2 are drawn with a dotted line. In a polarization inverted structure, plural band-like predetermined domains 2 are arranged on a crystal substrate face in parallel to each other, thus forming a stripe polarization inverted structure as a whole, which comprises a predetermined domain 2 to be polarization-inverted and a polarization non-inverted are alternately arranged.

In the production method of the present invention, the first electrode is first brought into contact with the inside of each predetermined domain 2 in a plate face (main surface) of a crystal substrate 1. The mode of contact area between the plate face and the first electrode at this time is important. As in one example shown in FIG. 1(b), in the present invention, the first electrode is broken to give small dot-like contact areas 3 that are dispersed like a mosaic within a predetermined domain, and the electrode is formed, which comprises these dot-like contact areas 3 collectively forming a predetermined domain 2 as a whole like a pointillistic drawing. Particularly, the definition of the size of each dot-like contact area 3 here is important, and the definition corresponds to the above-mentioned conditions (A). The above-mentioned conditions (A) are described in detail below.

Then, a second electrode as a lower electrode is contacted with the other plate face of a crystal substrate, and a polarization inversion voltage is applied. By the application of a polarization inversion voltage, polarization-inversion occurs in the above-mentioned dot-like contact areas and a production object of polarization inverted crystal is formed.

At this time, by selecting the shape of dot-like contact area, arrangement pattern, strength of polarization inversion voltage, and application time, a predetermined domain may take various modes as shown below, such as entirely polarization-inverted domain, assembly of small polarization-inverted domains and the like.

The above-mentioned mode (2) affords polarization inversion of the predetermined domain in its entirety. In this case, by appropriately selecting the shape of the dot-like contact area and arrangement pattern (mentioned below), and continuing the application of a polarization inversion voltage, polarization inverted domains spread from individual dot-like contact areas, are joined with each other, and finally integrated as shown in FIG. 1(c). At the time point when almost the whole predetermined domain 2 is filled with a polarization inverted domain 4, the object polarization inverted crystal is obtained.

In the above-mentioned mode (3), at least dot-like contact areas are polarization-inverted but the entirety of the predetermined domain is not completely polarization inverted. This mode can be said to be a mode wherein the predetermined domain is partially polarization-inverted like a pointillistic drawing by terminating the polarization-inversion prior to reaching the above-mentioned mode (2). In this case, the mode of partial polarization inversion falls under any of the above-mentioned modes (i)-(iv) by appropriately selecting the shape of the dot-like contact area and arrangement pattern (mentioned below), and further by selecting the application time of a polarization inversion voltage. These modes are explained using an enlarged view taking a rectangular contact area as an example. The arrangement pattern of the contact areas in the predetermined domain is as exemplarily shown in FIG. 1(b).

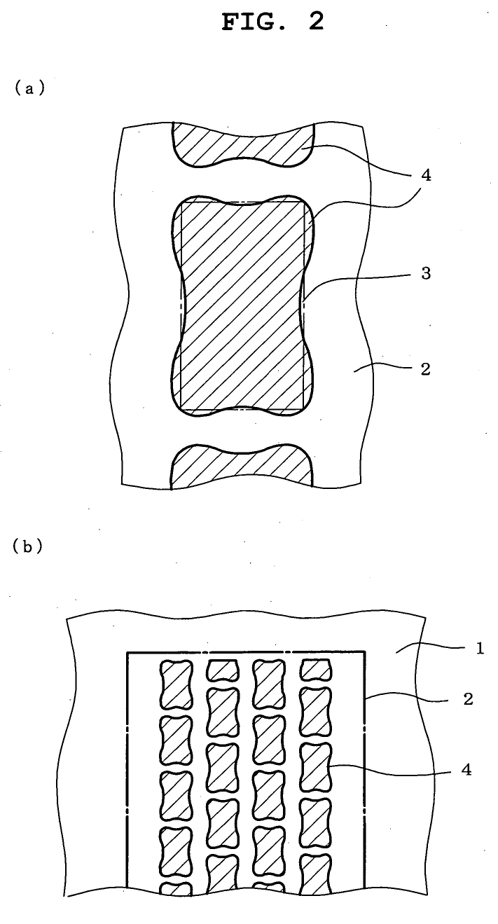

As shown in enlarged view of FIG. 2(a), the above-mentioned mode (i) comprises polarization inversion of a domain (solid line) 4 almost equal to a contact area 3 (dotted line).

Since polarization inversion tends to partially develop in a contact area and spread to the surrounding area, it is difficult to form a polarization inverted domain completely identical to the contact area. However, any polarization inverted domain having a shape considered to be generally equal to the contact area within the range of production error is within this mode. From the view of the entire predetermined domain after completion of the polarization inversion, it is appreciated that small polarization inverted domains 4 collectively constitute one pseudo polarization inverted domain (shape equal to predetermined domain 2) as a pointillistic drawing, as shown in FIG. 2(b).

In the above-mentioned mode (ii), individual contact areas are completely polarization-inverted and then polarization inversion further spreads outside the contact area, wherein polarization inverted domains spread from the neighboring contact areas are independently present without joining with each other (not shown). An assembly equivalent to the assembly of polarization inverted domains obtained by this mode (ii) can be obtained by enlarging, in the above-mentioned mode (i), the individual contact areas and narrowing the gap between them. Which mode is employed to obtain a similar final product can be determined in consideration of processing precision of the electrode, management of application time and the like.

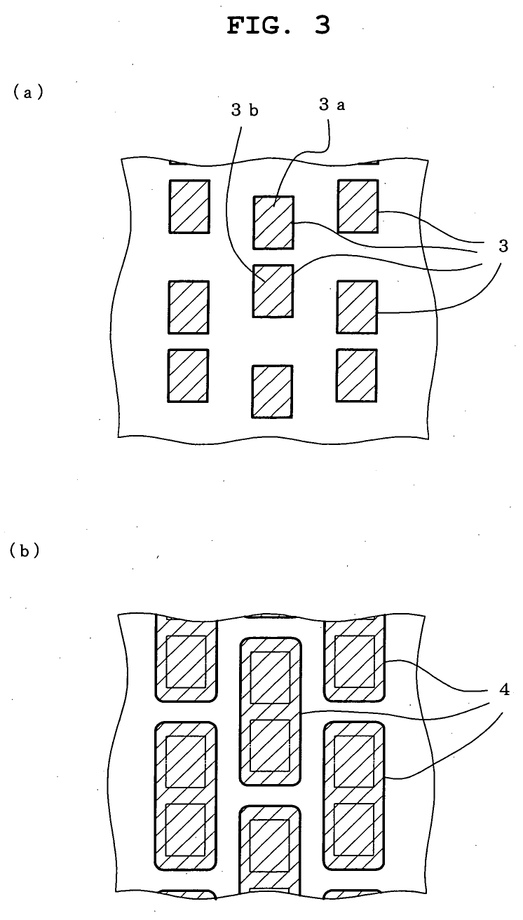

In the above-mentioned mode (iii), polarization inverted domains spread from the contact areas 3 of the first electrode as shown in FIG. 3(a) to the outside, and the regions located near in the polarization inverted domains are joined, as shown in FIG. 3(b). The arrangement pattern of the contact areas in this mode is one wherein the domains intended to be joined (e.g., a pair of contact areas 3a and 3b) are brought close to each other, as shown in FIG. 3(a). From the view of the whole predetermined domain after completion of the polarization inversion, while individual polarization inverted domains 4 become large because the domains are joined, small polarization inverted domains 4 collectively constitute one pseudo polarization inverted domain (shape equal to predetermined domain 2) as a pointillistic drawing, as shown in FIG. 2(b).

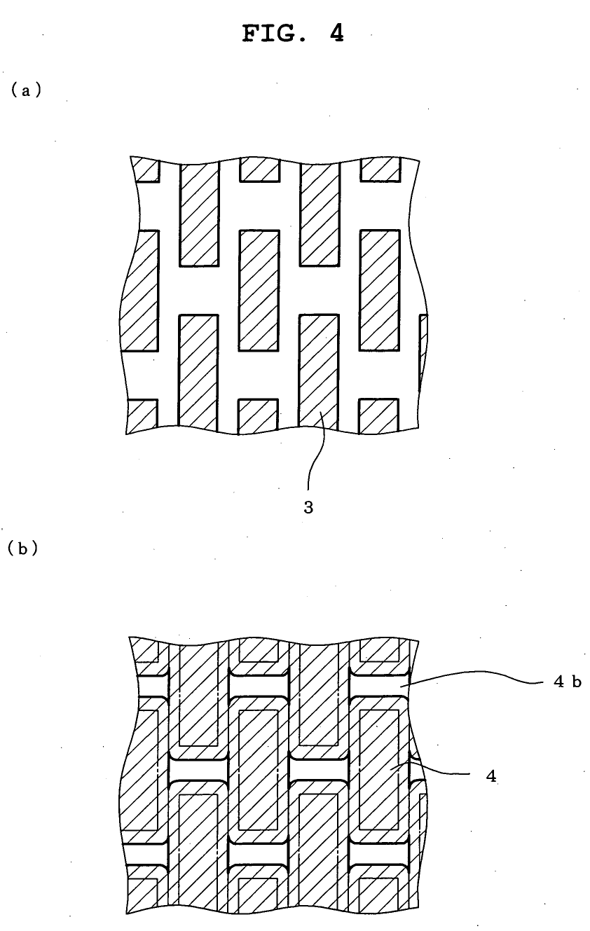

In the above-mentioned mode (iv), the polarization inverted domain spreads from the contact areas 3 of the first electrode as shown in FIG. 4(a) to the surrounding area, and all or the most part of the polarization inverted domains 4 are connected to become one but domains 4b free of polarization inversion remain, as shown in FIG. 4(b).

In the above-mentioned modes (i)-(iv), polarization inversion is stopped before polarization inverted domains that spread from the dot-like contact areas to the outside are joined with each other and completely fill the predetermined domain. Seen from the whole predetermined domain, entire inversion has not occurred. As compared to entire inversion of the predetermined domain, however, the dispersion in the total area of the inverted domain in the predetermined domain can be minimized. This means a smaller dispersion in the ratio (inversion ratio) of the inverted domain and the non-inverted domain when seen from the whole periodic polarization inverted structure (alternate arrangement structure of inverted domain and non-inverted domain), and possible achievement of more highly efficient quasi-phase matching. In addition, the dispersion of the quality of products becomes small and polarization inverted crystals having stable quality can be always obtained. Taking note of the action of the whole periodically polarization inverted structure, even if individual inversion domains are assemblies of small polarization inverted domains, they act on the propagated light as if the whole predetermined domains were polarization-inverted, thus providing quasi-phase matching comparable to conventional matching.

Using first electrode as an assembly of dot-like contact areas and dispersing them within the predetermined domain like a pointillistic drawing, almost the same edge effect is seen in any contact area, and inversion starts simultaneously from every contact area. In other words, when the whole predetermined domain is macroscopically seen, inconsistent phenomenon of early start of inversion depending on the position of the predetermined domain does not occur unlike conventional cases, and the following action and effect can be provided.

(a) An incident of preceding inversion of both ends alone does not occur, and even if the predetermined domain occupies a wide area, uniform polarization inverted domain is obtained in a short time since inversion starts simultaneously from each point. In addition, since the inversion completes in a short time, the part where inversion is started earlier does not spread in the period direction, unlike conventional cases.

(b) Even if the predetermined domain is variously changed in size, a similar inverted domain is always obtained by making the above-mentioned conditions (A) always the same, specific conditions for every kind of polarization inverted structure do not need to be set.

When a predetermined domain is polarization-inverted in its entirety, it is preferable that the predetermined domain 2 in FIG. 1(a) and the final polarization inverted domain 4 in FIG. 1(c) as a final product completely match. However, over and under inversions of the predetermined domain may be present as long as they are within the necessary quality range or the range of acceptable production error.

The above-mentioned conditions (A) define the presence of contact area in individual predetermined domains and can be divided into the following (A1) and (A2).

(A1) Plural dot-like contact areas are independently present like a mosaic in individual predetermined domains, and dispersed to form a predetermined domain as a whole like a pointillistic drawing.

(A2) Individual dot-like contact areas have an area of 0.00785 μm²-7850 μm² and a shape included in a circle with a diameter of 100 μm.

The above-mentioned conditions (A1) define dispersing dot-like contact areas in a predetermined domain, but do not limit that the individual contact areas are completely independent small areas having no contact point with each other.

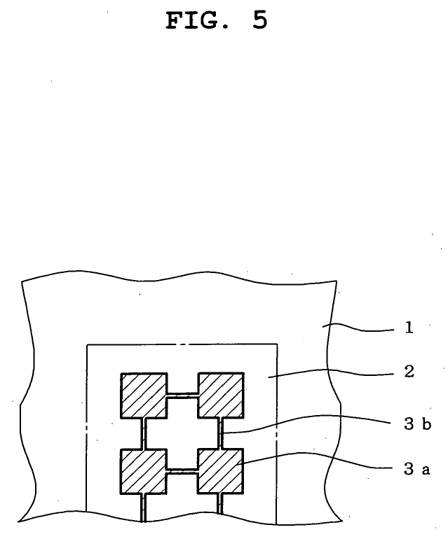

For example, even if the main parts (square) 3a of the dot-like contact areas are connected with each other by conductive paths 3b as shown in FIG. 5, such ultrafine conductive paths are ignored and the contact areas are considered to be substantially dispersed in a dot-like state, as long as the main parts 3a each satisfies the above-mentioned conditions (A2) and affords the above-mentioned action and effect of the present invention.

The above-mentioned conditions (A2) define the area and shape of individual contact areas such that they show a particular dot-like state capable of affording the above-mentioned action and effect. Limitation only on the area includes an excessively extended long shape. Such long shape causes polarization inversion only in both ends due to the edge effect similar to that mentioned in Prior Art, and inhibits the action and effect of the present invention. To prevent the contact area from being excessively deformed in a long shape, the deformation was limited to not exceed a circle having a particular diameter.

The individual contact areas have an area of 0.00785 μm²-7850 μm². When the area exceeds this range, individual contact areas become too large to realize an arrangement wherein small dot-like contact areas are gathered like a mosaic to draw a predetermined domain as a whole, and the above-mentioned action and effect cannot be achieved. When the area is less than this range, the contact areas are too small to be formed, and inversion cannot be performed. Of the above-mentioned area range, 1 μm²-100 μm² is particularly an optimal area to be dispersed in individual domains actually formed in a polarization inverted structure.

The shape of the individual contact areas may be any as long as they have the above-mentioned area and are included in a circle having a diameter of 100 μm, which exhibits the action and effect afforded by dividing into dots. The “included in a circle” contains being inscribed in the circle and equal to the circle.

In consideration of the size of the inverted domain in the polarization inverted structure actually used as well as unpreferable excessively long shape of a dot (inversion starts from both ends that are excessively apart), the diameter of the aforementioned circle is further limited and 50 μm, particularly about 10 μm, is preferable.

The shape of the contact areas is preferably square, rectangle, circular, ellipse (including oval having semicircle areas on both ends of a strip region in the longitudinal direction and deformed circle), equilateral triangle and the like, because the spread of polarization inversion from these shapes to the outside can be easily calculated. However, the shape may be any and is not limited to these, and may be polygon, star and the like. In addition, it may be a shape of polygon or any shape having round corners.

As explained in Prior Art, when the whole polarization inverted domain is seen, both ends of the band domain are problematically inverted due to an edge effect. When small contact areas are noted, conversely, pointed parts such as corners of polygon and the like are sometimes useful for the formation of an initial nucleus for inversion.

When dot-like contact areas are arranged in individual predetermined domains, the gap between the adjacent contact areas (namely, minimum distance) is preferably not more than 5 μm, by which the inverted domains are integrated in a short time.

As shown in FIG. 3, to join only the polarization inverted domains developed from particular contact areas (pair of 3a, 3b and the like), the gap between the domains desired to be joined alone only needs to be set narrower than the gap between the domains not intended to be joined, for example, not more than 5 μm and the like.

No limitation is imposed on which contact area having what shape is to be disposed in individual predetermined domains in what arrangement pattern, and the above-mentioned embodiments can be freely combined within the range satisfying the above-mentioned conditions (A).

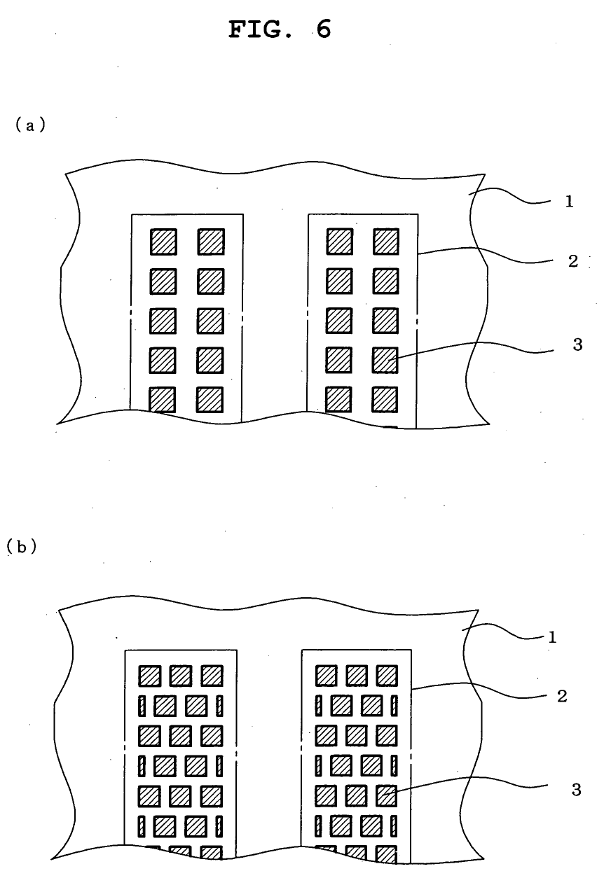

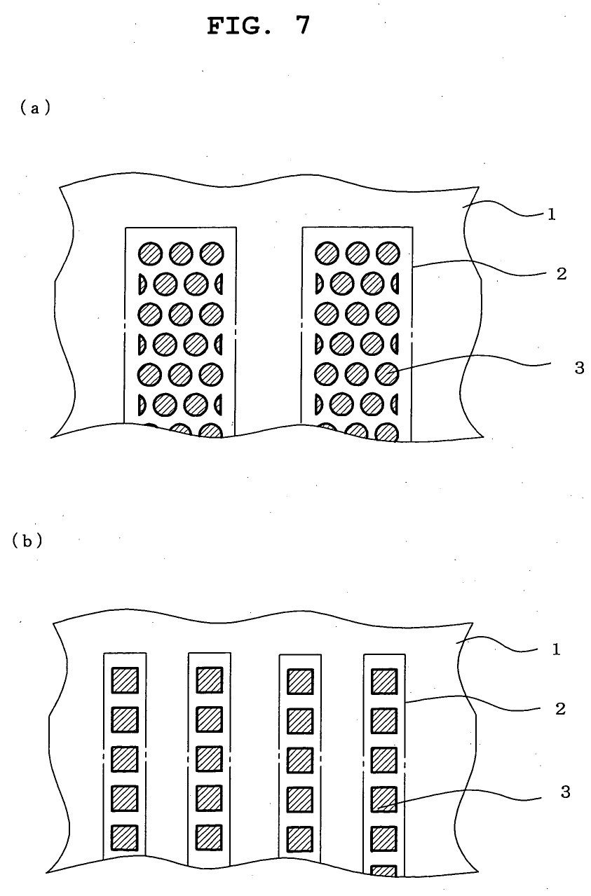

For example, in FIG. 6(a), square contact areas 3 are arranged regularly to form a matrix, and in FIG. 6(b), they are arranged by a half-pitch staggered for each row as in bricklaying. In FIG. 7(a), circular (or may be equilateral triangular) contact areas are densely arranged.

Of the above-mentioned combination embodiments, a combination wherein the contact areas are circles having a diameter of about 1 μm-2 μm, which are arranged to form a matrix pattern within a predetermined domain, and the total area is about 20%-60% of the area of the predetermined domain is particularly preferable because the predetermined domains can be simultaneously inverted.

When the band width (length in period direction) of the predetermined domains is narrow, dot-like contact areas form an arrangement pattern in one row in the longitudinal direction of the band, as shown in FIG. 7(b). In this case, too, as long as the above-mentioned conditions (A) are satisfied, the pattern may comprise contact areas having the same shape, which are arranged at a regular pitch, or contact areas having various shapes, which are arranged at irregular pitches.

When dot-like contact areas are dispersed in a predetermined domain, a suitable gap t1 (space free of contact area) suitable for the density is formed between the outer boundary of a predetermined domain and contact areas, whereby overflow of polarization inversion from a predetermined domain is preferably suppressed.

Since the inverted domain tends to spread beyond the contact area by not less than 1 μm², the aforementioned gap t1 is preferably not less than 1 μm.

The aforementioned gap t1 may be determined in association with the gap t2 between the adjacent contact areas, herein t1 is preferably a half of t2.

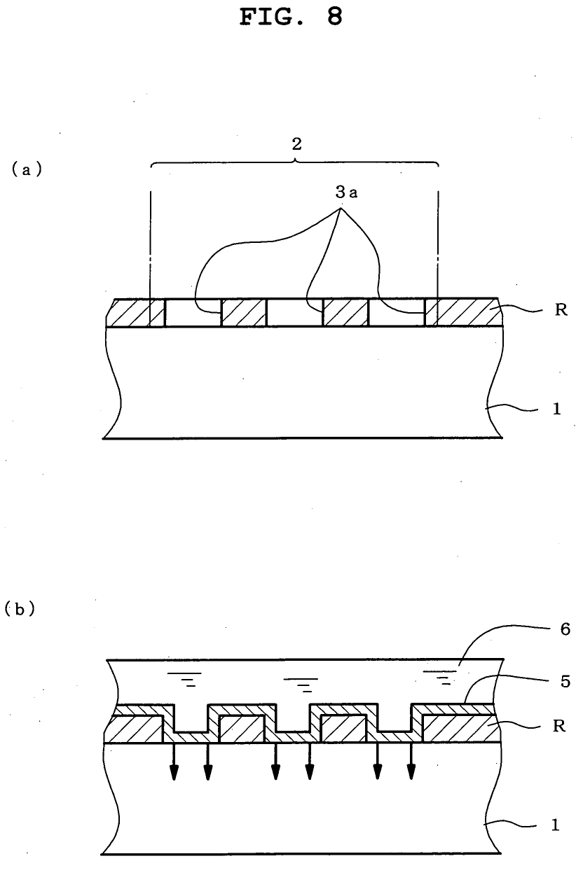

To form dot-like contact areas, a number of electrodes having a dot-like area are used and brought into contact with the crystal substrate face (not shown). In a preferable embodiment of an electrode, an insulation film R is formed on a plate face of a crystal substrate 1, and then openings 3a having the shape of the above-mentioned contact area is formed on the insulation film R to expose a plate face in the openings 3a, as shown in FIG. 8(a), and an electrode 5 is contacted with the exposed part to give a first electrode, as shown in FIG. 8(b), can be mentioned.

In the embodiment shown in FIG. 8(b), the whole insulation film R containing openings 3a is covered with an electrode layer 5, thus allowing contact of the electrode layer 5 with a dot-like crystal substrate exposed in the opening, whereby a dot-like contact area is obtained. For current-carrying to the electrode layer 5, moreover, a liquid electrode (electrolyte) 6 is brought into contact with the top surface of the electrode layer 5. The electric field produced in the crystal substrate by the application of a voltage is shown with an arrow.

As a material for the insulating layer, known materials such as PMMA (polymethacrylic acid methyl) and the like can be used and, as a forming method, film forming methods such as spin coat and the like can be used.

When patterning is necessary for the formation of an insulating layer, an electrode and the like, known patterning techniques such as photolithography and the like can be used.

For the formation of an electrode layer (metal electrode film), known film forming methods such as sputtering, electron beam vapor deposition and the like can be used.

As the liquid electrode, liquid electrolytes used for known liquid electrode methods, liquid metals such as gallium, indium, mercury and the like, and the like can be used.

As a solvent constituting a liquid electrolyte, water, polyol, a mixture of these, and the like can be mentioned. As a material of an electrolyte, lithium chloride, sodium chloride, potassium chloride and the like can be mentioned.

Moreover, for a container necessary for contacting a liquid electrode with the top surface of a metal electrode or a back face of a crystal substrate, a wire structure to be connected to a liquid electrode, and an electric power-supply unit (including control circuit and the like), those used for known liquid electrode methods can be used.

Polarization inversion is easily developed when the electric field acting on crystal is high, and tends to spread toward the surrounding area. An embodiment shown in FIG. 8(b) is considered, wherein the entire insulation film R including openings 3a is covered with an electrode layer 5, and the insulation film has a thin part and a thick part. In this case, the electric field acting on the crystal becomes higher in the part where the insulation film is thin than in the part where it is thick, and the polarization inverted part tends to spread beyond the contact areas.

Therefore, in an embodiment where an opening is formed in an insulation film and covered with a conductor, as in FIG. 8, the thickness of the insulation film is preferably such that the thickness of the insulation film between electrodes in the connecting direction of inverted domains is thinner than the thickness of other insulation films. As a result, the inverted domains spread with directional movement and only the domains to be connected are easily connected.

As a method of making an insulation film topically thin as mentioned above, for example, when a uniform photoresist is used, a resist layer between electrodes can be made thin by controlling the amount of UV exposure in a photolithography step. The amount of UV exposure can be controlled not only by changing the size intensity of light source but also by making the thickness variation of a photomask pattern.

A photomask limits the amount of UV radiation to the resist, and when the light-shielded part of a photomask is semitransparent (i.e., pale), that part of the resist is exposed to light to some extent, and when developed, that part of the resist is not completely removed but remains thin. In addition, an effect equivalent to the effect provided by making a thin resist can be provided by forming a photomask having a fine pattern (e.g., stripe, net, coil, free line pattern, dot-like and the like can be mentioned but not limited thereto) of not more than the patterning resolution, on a part to be topically made thin.

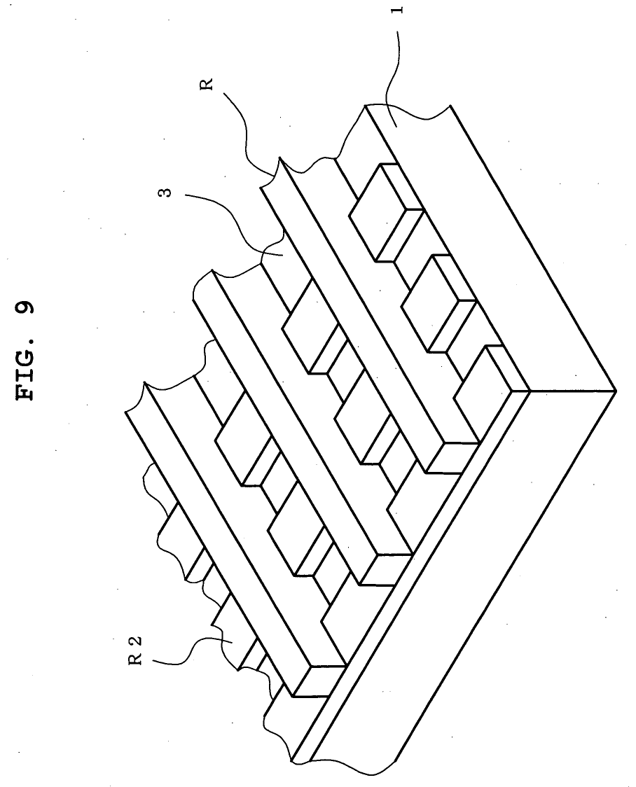

Another preferable embodiment wherein an opening is formed using an insulation film as mentioned above is explained below. FIG. 9 shows one example of the embodiment, wherein two kinds of stripe insulation films R1, R2 different from each other in at least the longitudinal direction of the band are layered intersectionally on one plate face of a crystal substrate 1. Exposed rectangular contact areas 3 are formed by surrounding four sides thereof with the bands R1, R2 of these two kinds of stripe insulation films, and an electrode is contacted with the domains 3 in the same manner as in FIG. 8 to give a first electrode.

As a production method of the two layer insulation film shown in FIG. 9, for example, a method wherein one stripe insulation film R1 is a layer made of SiO₂, the other stripe insulation film R2 is a photoresist layer, the insulation film R1 is vapor deposited on the substrate surface, a stripe structure is formed by photolithography, etching processing, and then the photoresist layer of the insulation film R2 is patterned by photolithography, and the like can be mentioned.

According to such production method, the thickness of each layer can be independently controlled freely since production conditions for each layer are independent, and a mask layer having different thickness for every direction can be easily produced. When an equivalent structure is to be produced with a single layer, photomask processing or patterning conditions of photolithography is/are limited, making production difficult.

In an embodiment using a two-layer stripe insulation film as shown in FIG. 9, the direction of the two stripes may be any, but it is preferable to make them mutually perpendicular to give quadrel contact areas, and to match the direction of one stripe (i.e., direction of one side of quadrel contact area) with the longitudinal direction of the band of the predetermined domain.

The nonlinear optical crystal may be known. For example, representative ones such as LiNbO₃, LiTaO₃, X_{A}TiOX_{B}O₄ (X_{A}=K, Rb, Tl, CS, X_{B}=P, As) and the like, and these doped with various other elements such as Mg and the like can be mentioned. LiNbO₃ and LiTaO₃ may be congruent compositions or stoichiometric compositions.

Ferro-electric crystals such as LiNbO₃, LiTaO₃ and the like have been preferably used as materials of the elements to be subjected to wavelength conversion, such as second harmonic generation, Optical Parametric Oscillation or amplification, Difference Frequency Generation, Sum Frequency Generation and the like. MgO-doped LiNbO₃ is a material particularly superior in the resistance to optical damage.

The crystal substrate to be subjected to polarization inversion processing is representatively a z plate. It may be an off-cut plate wherein a particular crystal axis forms a particular angle (off angle) with the normal line of the substrate surface. A z plate is a crystal substrate so cut that the direction of the Z axis of the crystal is perpendicular to the substrate surface (i.e., Z-cut). A crystal substrate is preferably a single domain (single polarization treatment) in its entirety having the same polarization direction.

When a crystal substrate which has been so cut that the Y axis of the crystal axis is contained in the main surface of a crystal substrate, as represented by Z plate, is used, in one of the preferable embodiments, plural contact areas present in the domain to be polarization-inverted are disposed to lie in continuance in the Y axis direction. Since ferro-electric crystals such as LiNbO₃, LiTaO₃ and the like (including these doped with impurity such as MgO and the like) show easy growth of an inverted domain in the Y axis direction, a predetermined band domain is easily formed by disposing, on the surface of the crystal substrate such as Z plate and the like, contact areas to lie in continuance in the Y axis direction.

While the size of a crystal substrate is not limited, as an exemplary size of a cuboid plate, the length in the light path direction is about 5 mm-70 mm, the size of the section perpendicular to the light path direction is about (3 mm×70 mm)-(0.2 mm×5 mm). A polarization inverted crystal formed in such size can be used as it is or after freely dividing or processing.

In the wavelength conversion according to quasi-phase matching methods using a polarization inverted structure, maximum conversion efficiency (m=1) depends on a polarization inversion ratio D, wherein the most ideal value is D=1/2, namely, when the band width (domain width) of a polarization inverted domain is half the polarization inversion period, the conversion efficiency is highest as a wavelength conversion element. Thus, when a periodic polarization inverted structure is to be produced, what is most important is to produce every polarization inverted domain disposed in a stripe, such that every domain shows a polarization inversion ratio of 50% with uniform precision.

According to the production method of the present invention, due to the generation of polarization inverted domain from contact areas dispersed and gathered like a pointillistic drawing, any polarization inverted domain and any part of individual polarization inverted domains become uniform.

The voltage to be applied for polarization inversion may be determined by reference to known polarization inversion techniques. For example, a method comprising application of a direct voltage for a given time, and a method comprising application of a pulse voltage can be mentioned. A voltage is applied in the direction that makes the potential relatively positive in the +z-plane and relatively negative in the −z-plane. Particularly, the action and effect of the dot-like electrodes dispersed according to the production method of the present invention become most remarkable when a pulse voltage is applied. Application of the pulse voltage facilitates simultaneous inversion of the entire domains, and improves content uniformity of the inverted structure.

### EXAMPLES

The production method of the present invention is described in detail in the following by showing Examples.

### Example 1

In this Example, the shape of the dot-like contact area was ellipse (oval wherein both ends in the longitudinal direction of a band domain are each a semicircle, which can be also said to be an oval obtained by making round corners of a rectangle), and band-like polarization inverted domains had various sizes in the longitudinal direction. Each sample was subjected to polarization inversion.

As a crystal substrate, a 0.3 mm-thick Z cut LiNbO₃ (hereinafter to be indicated as “MgO:LN”) containing MgO by 5 mol % was used.

As to the design specification of the polarization inverted structure to be produced, the size of a polarization inverted structure as a whole on a crystal substrate surface was structure width (longitudinal direction of stripe) 1 mm, length of structure in the light path direction 15 mm, polarization inversion period 7.0 μm, and inversion ratio 50%.

Thus, the shape of the individual predetermined domains was a rectangle wherein the length of the stripe in the longitudinal direction (longitudinal direction of band) was 1 mm and the length in the period direction (band width direction) was 3.5 μm.

MgO: An insulation film was formed on a +z-plane of an LN substrate and an insulation film having dot-like holes was formed with photoresist.

The shape of the holes to be the dot-like contact areas was ellipse (oval) as mentioned above, and respective samples having a length in the longitudinal direction of band ranging from 1.0 μm as the minimum size up to 500 μm were produced. The length of the contact area in the period direction of the stripe (band width direction) was constantly 2.0 μm, and the gap between the adjacent contact areas in the same predetermined domain was constantly 1 μm.

A metal film was formed on the entire surface of the insulation film by sputtering (lower layer Cr/upper layer Au) and the electrode membrane was also contacted with the substrate surface exposed in the opening.

A pulse voltage was applied between substrate ±Z planes using an LiCl electrolyte solution to invert the dot portion where the metal film was in contact with the substrate.

The metal film and photoresist were removed, selective etching was performed using fluoro-nitric acid and the polarization inverted structure was observed from the substrate surface and the substrate section. As a result, it was confirmed that a uniform periodic inverted structure had been formed over the entire area of the structure of every sample.

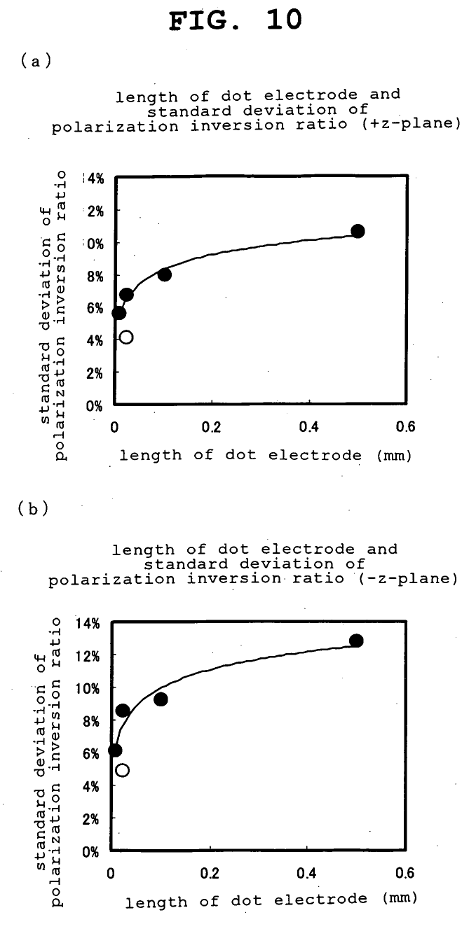

In addition, the relationship between the size of the dot-like contact area and the polarization inversion ratio (polarization inversion width/polarization inversion period) was evaluated for the above-mentioned samples. For comparison of the inversion shape distribution, dispersion of the inversion ratios of the +z-plane and the −z-plane was expressed by the standard deviation value. The results are shown in FIG. 10, graphs (a), (b) by plotting with black circles.

As is clear from the graph of FIG. 10, the standard deviation became exponentially smaller with decreasing dot-like contact areas, resulting in smaller variation. In addition, it was found that the variation was greater in the −z-plane which is a uniform electrode.

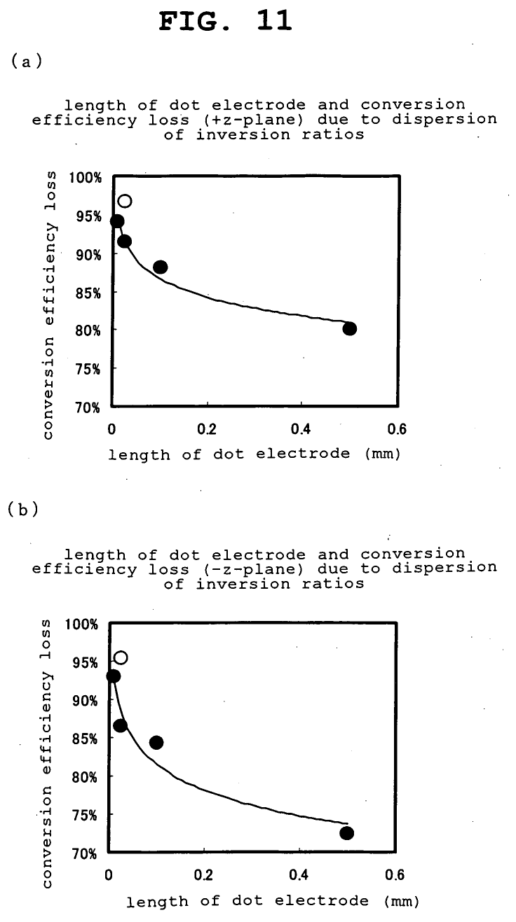

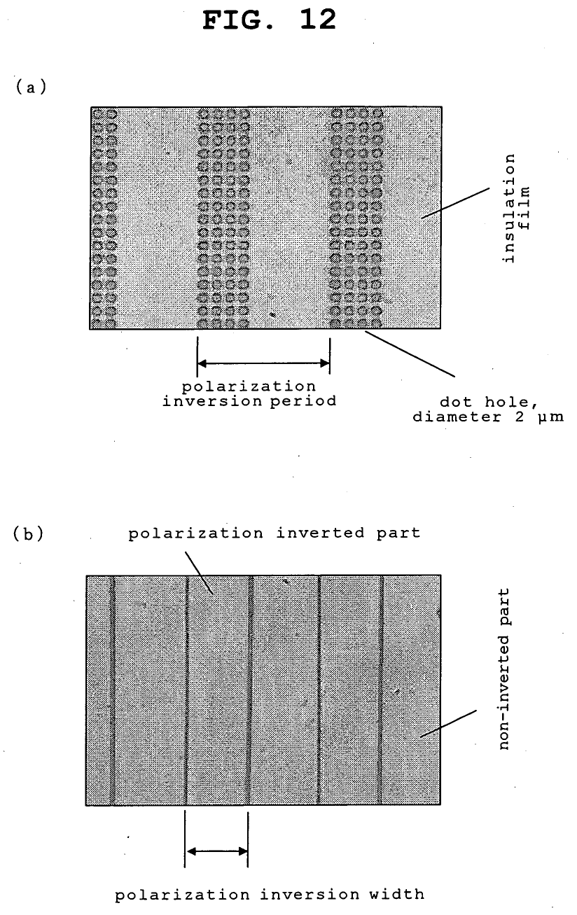

The dispersion of the inversion ratio causes lower conversion efficiency. The dispersion of the inversion ratio as shown in the graphs of FIG. 10(a), (b) was converted to conversion efficiency (conversion efficiency in the absence of dispersion is 100%), and shown in the graphs of FIG. 11(a), (b) by plotting with black circles. As is clear from the graphs in this Figure, an inflection point relating to the high-low of conversion efficiency was present around the dot size of about 100 μm.

As shown in FIG. 11(b), it is clear that the size of the dot affording not less than 80% of the conversion efficiency is not more than 100 μm in the −z-plane where the conversion efficiency is generally low.

### Example 2

In this Example, a 0.5 mm-thick Z cut MgO:LN containing MgO by 5 mol % was used as a crystal substrate.

As to the design specification of the polarization inverted structure to be produced, the size of a polarization inverted structure as a whole on a crystal substrate surface was longitudinal direction 10 mm, the light path direction 30 mm, period 30 μm, and diameter of dot-like contact area 2 μm.

The arrangement pattern of the contact areas was a matrix, as shown in FIG. 12(a). The designed width of the predetermined domain in the period direction was 15 μm, and a space (area free of contact area) of 2 μm was formed on both ends. The areas were disposed in the center of a band width of 11 μm with a gap between the contact areas of 1 μm (i.e., center to center pitch 3 μl).

Polarization inversion was performed in the same manner as in Example 1, and the obtained polarization inverted structure was observed. As a result, it was confirmed that a uniform periodically inverted structure had been formed over the entire area of the polarization inverted structure, as shown in FIG. 12(b).

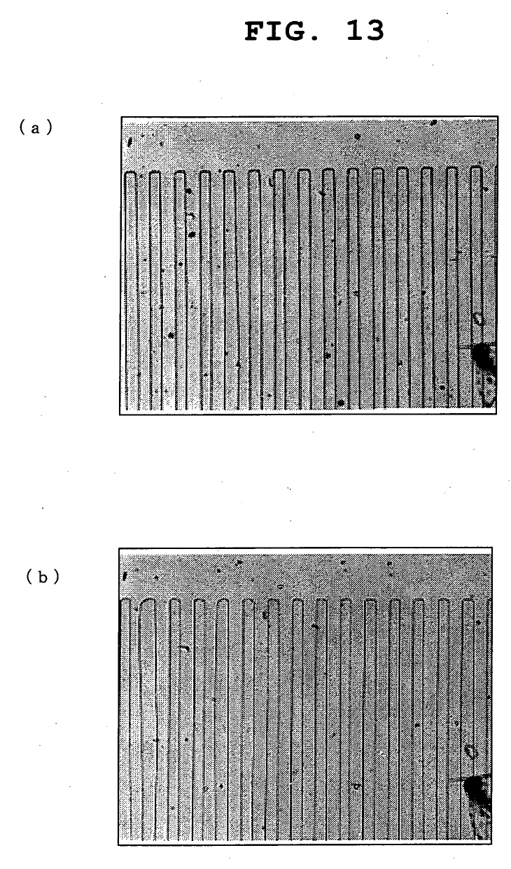

In addition, the end of each inversed domain (band-like) of the obtained polarization inverted structure was observed. As shown in FIG. 13(a) providing a microscopic photograph of the +z-plane side of the end and FIG. 13(b) providing a microscopic photograph of the −z-plane side of the end, the edge effect was found to have been preferably suppressed to obliterate overflow from the predetermined domain.

### Comparative Example 1

In the same manner as in the above-mentioned Example 2, a polarization inverted structure having the same specification as in the above-mentioned Example 2 was formed according to a conventional method except that a metal electrode was brought into contact with the entire surface of the predetermined domain, and the quality was compared.

First, as regards the inversion width, it was wider by 3-4 μm in Comparative Example than the electrode width, but the one obtained in Example 2 showed a suppressed width of 1 μm.

Furthermore, the dispersion in polarization inversion ratios (inversion width/inversion period) was compared in terms of standard deviation value. As a result, the product of Comparative Example showed dispersion of 9%-10% (2.2 μm-2.4 μm in width) in the +z-plane, and 12%-14% (2.9 μm-3.4 μm in width) in the −z-plane. The product obtained in Example 2 showed dispersion of 4% in the +z-plane and 5% in the −z-plane, thus affording markedly improved dispersion in the polarization inversion ratio.

### Example 3

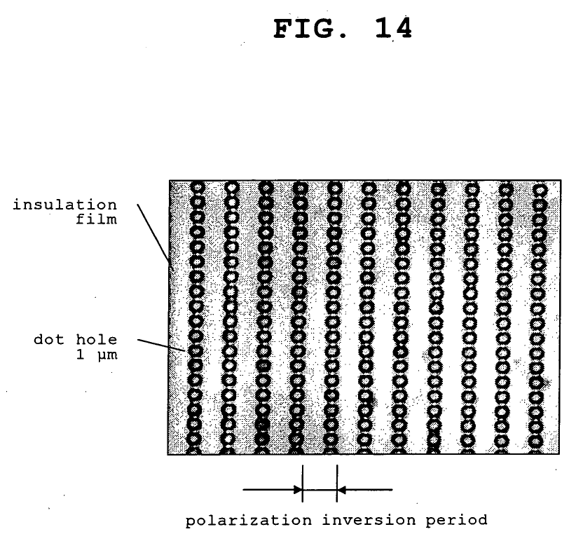

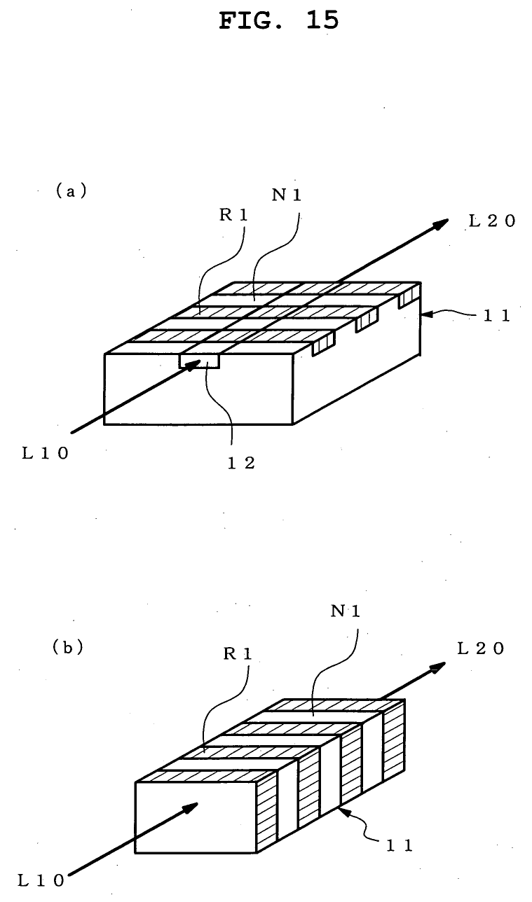

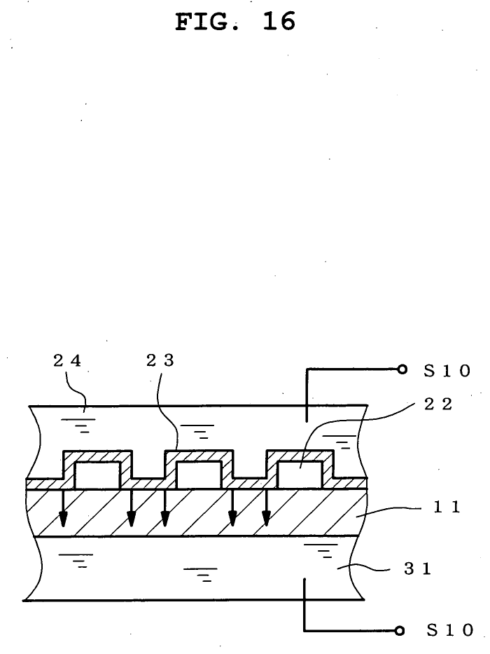

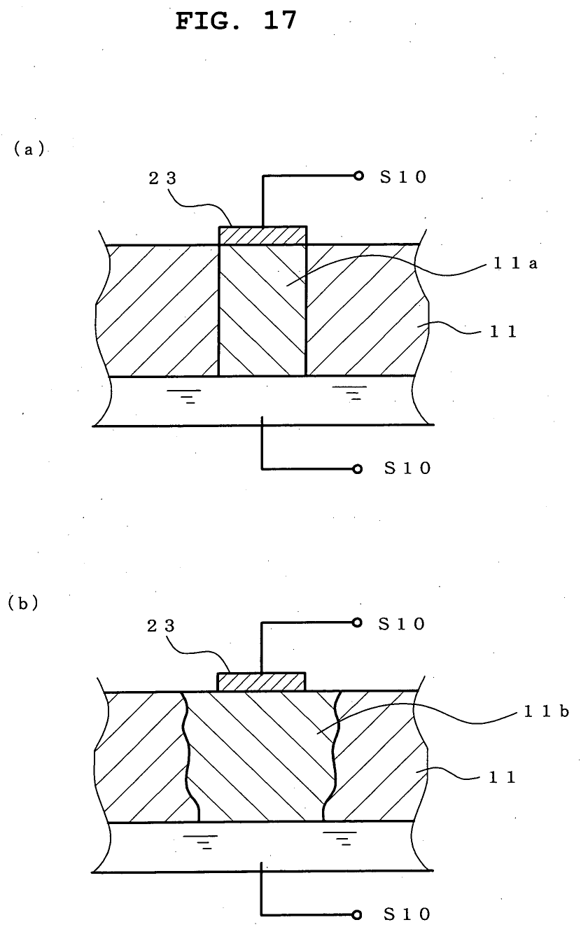

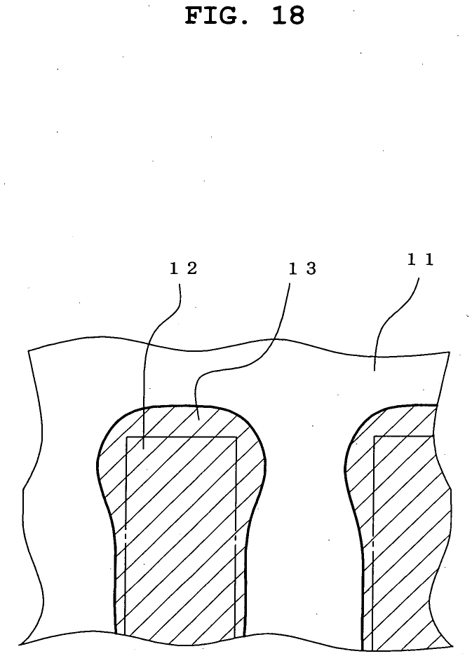

In this Example, a crystal substrate similar to that in Example 1 was used, and dot-like contact areas, which were circles having a diameter of 1 μm, were arranged to form one line at period 7.0 μm in the longitudinal direction of the predetermined domain, as shown in FIG. 14.

By the process similar to that in Example 1, an electrode was formed in the +z-plane of a substrate, and a voltage was applied to form polarization inversion.

After the inversion, the inverted structure was confirmed by selective etching using fluoro-nitric acid. As a result, it was found that the uniformity of the inversion ratio had been markedly improved as compared to conventional methods.

The dispersion in polarization inversion ratios (inversion width/inversion period) was compared in terms of standard deviation value. As a result, the product produced by conventional methods showed dispersion of 11.9% (0.83 μm in inversion width) in the +z-plane, and 15% (1.05 μm in inversion width) in the −z-plane. The product obtained in this Example showed dispersion of 4% in the +z-plane (0.28 μm in inversion width), and 5% in the −z-plane (0.35 μm in inversion width), thus affording markedly improved dispersion.

### Example 4

In this Example, a crystal substrate similar to that in Example 1 was used and, as the design specification of the polarization inverted structure to be produced, the size of a polarization inverted structure as a whole on a crystal substrate surface was longitudinal direction 10 mm, the light path direction 50 mm, period 18 μm, and dot-like contact areas (square with one side 7 μm). In the same manner as in Example 1, polarization inversion was performed.

After the inversion, the inverted structure was confirmed by selective etching using fluoro-nitric acid. As a result, it was found that the uniformity of the inversion ratio had been improved as compared to conventional methods.

### Example 5

In this Example, in a polarization inversion test under the same conditions as in Example 1, the size of the contact area (ellipse) in the longitudinal direction was 25 μm and the application of voltage was stopped in the polarization inversion step before polarization inverted domains that spread from the neighboring contact areas were bonded to each other.

The size of the gap (non-inverted part) left between polarization inverted domains was 1.5 μm on average.

The dispersion in the inversion ratio was examined along the light path direction of the inverted domain alone, while ignoring the part free of bonding. As a result, the dispersion was 4.1% for the +z-plane containing contact areas and 5.8% for the −z-plane on the back. The results are shown in the graphs of FIG. 10(a), (b) by plotting with while circles.

In contrast, in the sample of Example 1 wherein a voltage was continuously applied until the inverted domains were integrated, and the whole predetermined domain was polarization-inverted. The dispersion in the inversion ratio along the light path direction was 6.7% for +z-plane and 8.6% for the −z-plane on the back.

From these results, it was found that dispersion of inversion ratio was suppressed in the embodiment of the above-mentioned (3), wherein the inversion was stopped before completion of the polarization-inversion of the entire inner surface of the predetermined domain, to about half that in the embodiment of the above-mentioned (2), wherein the entire inner surface of the predetermined domain was polarization-inverted.

### INDUSTRIAL APPLICABILITY

As explained above, according to the production method of the present invention, a high quality polarization inverted crystal can be obtained more easily.

This application is based on a patent application No. 20 03-070802 filed in Japan, the contents of which are hereby inco rporated by reference.

1. A production method of a polarization inverted crystal, which comprises a step of bringing a first electrode into partial contact with domain(s) to be polarization-inverted, which domains are present in the number of not less than 1 in one plate face of a nonlinear optical crystal substrate, bringing a second electrode into contact with the other plate face of the substrate, and applying a polarization inversion voltage between the both electrodes,
wherein, in the aforementioned step, the electrodes are so formed that the contact area of the first electrode relative to the plate face satisfies the conditions of the following (A), and the domain to be polarization-inverted is entirely or partially polarization-inverted by the application of a polarization inversion voltage:
(A) respective contact areas are dispersed like dots in individual domains to be polarization-inverted such that plural contact areas are independently present, and individual dot-like contact areas have an area of 0.00785 μm²-7850 μm² and a shape included in a circle with a diameter of 100 μm.

2. The production method of claim 1, wherein the domain to be polarization-inverted is entirely polarization-inverted by the application of a polarization inversion voltage.

3. The production method of claim 1, wherein the domain to be polarization-inverted is partially polarization-inverted by the application of a polarization inversion voltage and the partial polarization inversion is any of the modes of the following (i)-(iv):
(i) a mode wherein an area about the same as the contact area of the first electrode is polarization-inverted,
(ii) a mode wherein the polarization inverted domain spreads from the contact area of the first electrode to a surrounding area, and the polarization inverted domains are not joined with each other but independently present,
(iii) a mode wherein the polarization inverted domain spreads from the contact area of the first electrode to a surrounding area, and partial areas of the polarization inverted domain are joined with each other, and
(iv) a mode wherein the polarization inverted domain spreads from the contact area of the first electrode to a surrounding area, the polarization inverted domains are joined with each other but an area free of polarization-inversion remains.

4. The production method of claim 1, wherein an insulation film is formed on one plate face of the nonlinear optical crystal substrate, an opening having a shape of said contact area is formed in the insulation film to expose the plate face within the opening, and an electrode is contacted with the exposed plate, which is used as the first electrode.

5. The production method of claim 1, wherein two kinds of stripe insulation films different from each other in at least the longitudinal direction of these bands are layered intersectionally on one plate face of the nonlinear optical crystal substrate, an exposed area surrounded by belts of these two kinds of stripe insulation films is used as said contact area, and an electrode is contacted with said area to give the first electrode.

6. The production method of claim 1, wherein said contact area has a shape of a circle, an ellipse or a polygon with round corners.

7. The production method of claim 1, wherein a gap between the adjacent areas from the plural contact areas present in the domain to be polarization-inverted is not more than 5 μm under said conditions (A).

8. The production method of claim 1, wherein the nonlinear optical crystal substrate is a crystal substrate which is so cut that the substrate contains the Y crystal axis in its main face, and the plural contact areas present in the domain to be polarization-inverted are arranged to lie in continuance in the Y axis direction under said conditions (A).

9. The production method of claim 1, wherein the nonlinear optical crystal substrate is a crystal substrate made of LiNbO₃, LiTaO₃, or LiNbO₃ or LiTaO₃ doped with other element.
